(19) United States
(12) Patent Application Publication
(10) Pub. No.: US 2025/0125223 A1
(43) Pub. Date: Apr. 17, 2025

(54) PASSIVATION STRUCTURE AND THE METHODS OF FORMING THE SAME

(71) Applicant: Taiwan Semiconductor Manufacturing Co., Ltd., Hsinchu (TW)

(72) Inventors: Wan-Yu Lee, Taipei City (TW); Ta-Hsuan Lin, Hsinchu (TW); Hua-Wei Tseng, New Taipei City (TW); Wei-Cheng Wu, Hsinchu (TW)

(21) Appl. No.: 18/415,426

(22) Filed: Jan. 17, 2024

Related U.S. Application Data
(60) Provisional application No. 63/590,810, filed on Oct. 17, 2023.

(51) Int. Cl. H01L 23/48; H01L 21/768; H01L 23/00; H01L 23/31; H01L 23/498; H01L 25/00; H01L 25/065

(52) U.S. Cl. CPC H01L 23/481; H01L 21/76829; H01L 23/3128; H01L 23/49822; H01L 24/32; H01L 24/94; H01L 25/0655; H01L 25/50; H01L 2224/32225; H01L 2224/94; H01L 2924/181

(57) ABSTRACT

A method includes forming a metal pad, depositing a passivation layer on the metal pad, and planarizing the passivation layer, so that the passivation layer includes a planar top surface. The method further includes etching the passivation layer to form an opening in the passivation layer, wherein the metal pad is exposed to the opening, and forming a conductive via including a lower portion in the opening, and an upper portion higher than the passivation layer. A polymer layer is then dispensed to cover the conductive via.

### PRIORITY CLAIM AND CROSS-REFERENCE

This application claims the benefit of the following provisionally filed U.S. Patent application: Application No. 63/590,810, filed on Oct. 17, 2023, and entitled “Flat Passivation Structure for InFO and InFO-POP,” which application is hereby incorporated herein by reference.

### BACKGROUND

In the formation of integrated circuits, integrated circuit devices such as transistors are formed at the surface of a semiconductor substrate in a wafer. An interconnect structure is then formed over the integrated circuit devices. A metal pad is formed over, and is electrically coupled to, the interconnect structure. A passivation layer and a first polymer layer are formed over the metal pad, with the metal pad exposed through the openings in the passivation layer and the first polymer layer. The first polymer layer has the function of buffering stress.

A metal via may then be formed to connect to the top surface of the metal pad, followed by the formation of a second polymer layer over the redistribution line.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 9 illustrate the cross-sectional views of intermediate stages in the formation of a device die in accordance with some embodiments.

FIGS. 10 through 16 illustrate the cross-sectional views of intermediate stages in the formation of a package including a device die in accordance with some embodiments.

FIG. 17 illustrates an integrated fanout package in accordance with some embodiments.

FIGS. 18A, 18B, and 18C illustrate the packages and the respective line vias and copper vias in accordance with some embodiments.

FIG. 19 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package including a device die comprising a passivation layer having a flat top surface and the method of forming the same are provided. In accordance with some embodiments of the present disclosure, a passivation layer is deposited on metal pads, and is planarized in a planarization process to have a planar top surface. The passivation layer is then patterned, and line vias and pillar vias are formed to penetrate through the passivation layer. By planarizing the passivation layer to have the planar top surface, the thickness of the passivation layer is reduced. Furthermore, the patterning process is performed through a photolithography process, so that the pitches of the line vias and pillar vias are reduced to meet the requirement of advanced integrated circuits.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

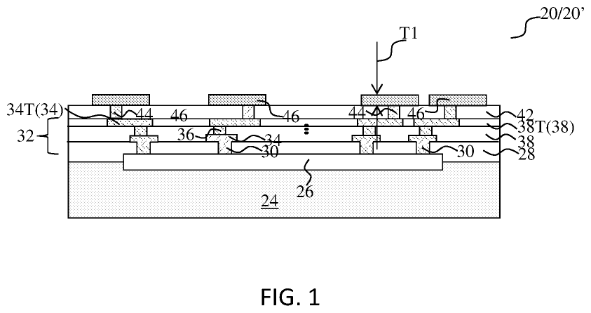

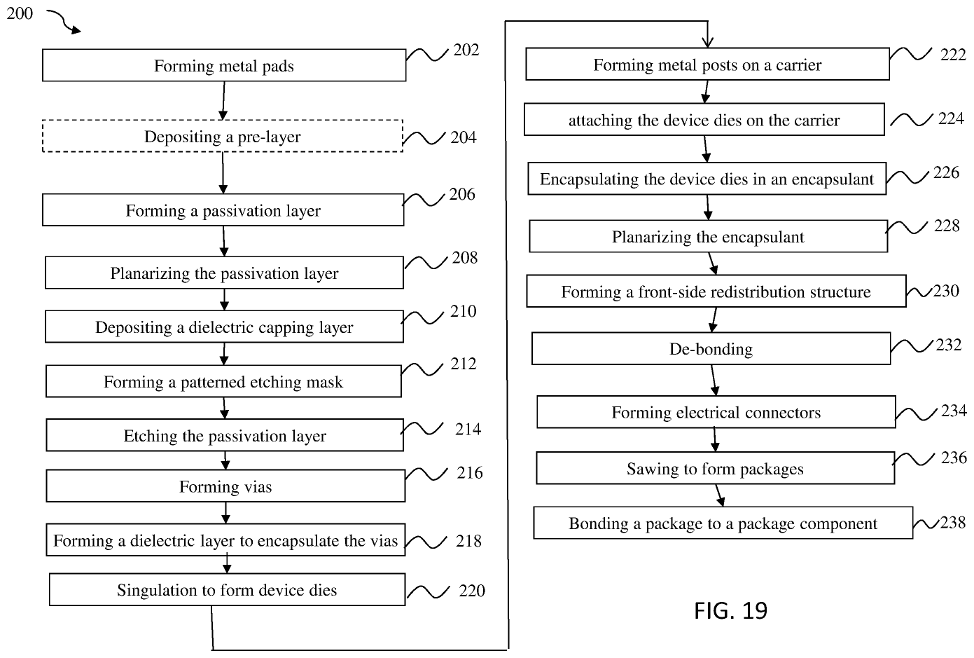

FIGS. 1 through 16 illustrate the cross-sectional views of intermediate stages in the formation of a package in accordance with some embodiments of the present disclosure. The corresponding processes are also reflected schematically in the process flow shown in FIG. 19.

FIG. 1 illustrates a cross-sectional view of (integrated circuit) device 20. In accordance with some embodiments of the present disclosure, device 20 is or comprises a device wafer including active devices and possibly passive devices, which are represented as integrated circuit devices 26. Device 20 may include a plurality of chips (device dies) 20′ therein, with one of chips 20′ being illustrated. In accordance with alternative embodiments of the present disclosure, device 20 is an interposer wafer, which is free from active devices, and may or may not include passive devices. In accordance with yet alternative embodiments of the present disclosure, device 20 is or comprises a package substrate strip, which includes a core-less package substrate or a cored package substrate with a core therein. In subsequent discussion, a device wafer is used as an example of device 20, and device 20 may also be referred to as wafer 20. The embodiments of the present disclosure may also be applied on interposer wafers, package substrates, packages, etc.

In accordance with some embodiments of the present disclosure, wafer 20 includes semiconductor substrate 24 and the features formed at a top surface of semiconductor substrate 24. Semiconductor substrate 24 may be formed of or comprise crystalline silicon, crystalline germanium, silicon germanium, carbon-doped silicon, or a III-V compound semiconductor such as GaAsP, AlInAs, AlGaAs, GaInAs, GaInP, GaInAsP, or the like. Shallow Trench Isolation (STI) regions (not shown) may be formed in semiconductor substrate 24 to isolate the active regions in semiconductor substrate 24.

In accordance with some embodiments of the present disclosure, wafer 20 includes integrated circuit devices 26, which are formed on the top surface of semiconductor substrate 24. Integrated circuit devices 26 may include Complementary Metal-Oxide Semiconductor (CMOS) transistors, resistors, capacitors, diodes, and the like in accordance with some embodiments. The details of integrated circuit devices 26 are not illustrated herein. In accordance with alternative embodiments, wafer 20 is used for forming interposers (which are free from active devices).

Inter-Layer Dielectric (ILD) 28 is formed over semiconductor substrate 24 and fills the spaces between the gate stacks of transistors (not shown) in integrated circuit devices 26. In accordance with some embodiments, ILD 28 is formed of silicon oxide, Phospho Silicate Glass (PSG), Boro Silicate Glass (BSG), Boron-doped Phospho Silicate Glass (BPSG), Fluorine-doped Silicate Glass (FSG), or the like. ILD 28 may be formed using spin-on coating, Flowable Chemical Vapor Deposition (FCVD), or the like. In accordance with some embodiments of the present disclosure, ILD 28 may also be formed using a deposition method such as Plasma Enhanced Chemical Vapor Deposition (PECVD), Low Pressure Chemical Vapor Deposition (LPCVD), or the like.

Contact plugs 30 are formed in ILD 28, and are used to electrically connect integrated circuit devices 26 to overlying metal lines and vias. In accordance with some embodiments of the present disclosure, contact plugs 30 are formed of or comprise a conductive material selected from tungsten, aluminum, copper, titanium, tantalum, titanium nitride, tantalum nitride, alloys therefore, and/or multi-layers thereof. The formation of contact plugs 30 may include forming contact openings in ILD 28, filling a conductive material(s) into the contact openings, and performing a planarization process (such as a Chemical Mechanical Polish (CMP) process or a mechanical grinding process) to level the top surfaces of contact plugs 30 with the top surface of ILD 28.

Interconnect structure 32 is formed over integrated circuit devices 26. Interconnect structure 32 includes metal lines 34 and vias 36, which are formed in dielectric layers 38 (also referred to as Inter-metal Dielectrics (IMDs)) and etch stop layers (not shown). The metal lines at a same level are collectively referred to as a metal layer hereinafter. In accordance with some embodiments of the present disclosure, interconnect structure 32 includes a plurality of metal layers including metal lines 34 that are interconnected through vias 36. Metal lines 34 and vias 36 may be formed of copper or copper alloys, and can also be formed of other metals.

In accordance with some embodiments of the present disclosure, dielectric layers 38 are formed of low-k dielectric materials. The dielectric constants (k values) of the low-k dielectric materials may be lower than about 3.5, for example. Dielectric layers 38 may comprise a carbon-containing low-k dielectric material, Hydrogen SilsesQuioxane (HSQ), MethylSilsesQuioxane (MSQ), or the like. The etch stop layers are formed underlying the respective dielectric layers 38, and may be formed of or comprise aluminum nitride, aluminum oxide, silicon oxycarbide, silicon nitride, silicon carbide, silicon oxynitride, or the like, or multi-layers thereof.

The formation of metal lines 34 and vias 36 may include single damascene processes and/or dual damascene processes. In a single damascene process for forming a metal line or a via, a trench or a via opening is first formed in one of dielectric layers 38, followed by filling the trench or the via opening with a conductive material. A planarization process such as a Chemical Mechanical Polish (CMP) process is then performed to remove the excess portions of the conductive material higher than the top surface of the dielectric layer, leaving a metal line or a via in the corresponding trench or via opening. In a dual damascene process, both of a trench and a via opening are formed in a dielectric layer, with the via opening underlying and connected to the trench. Conductive materials are then filled into the trench and the via opening to form a metal line and a via, respectively. The conductive materials may include a diffusion barrier layer and a copper-containing metallic material over the diffusion barrier layer. The diffusion barrier layer may include titanium, titanium nitride, tantalum, tantalum nitride, or the like.

Metal lines 34 include top conductive (metal) features (denoted as 34T) such as metal lines, metal pads, or vias in a top dielectric layer (denoted as dielectric layer 38T), which is the top layer of dielectric layers 38. In accordance with some embodiments, dielectric layer 38T is formed of a low-k dielectric material similar to the material of lower ones of dielectric layers 38. The metal features 34T in the top dielectric layer 38T may also be formed of copper or a copper alloy, and may have a dual damascene structure or a single damascene structure.

In accordance with some embodiments, an etch stop layer (not shown) may be deposited on the top dielectric layer 38T and the top metal layer. The etch stop layer may be formed of or comprise silicon nitride, silicon oxide, silicon oxycarbide, silicon oxynitride, or the like.

Passivation layer 42 (sometimes referred to as passivation-1 or pass-1) is formed over etch stop layer 40. In accordance with some embodiments, passivation layer 42 is formed of a non-low-k dielectric material having a dielectric constant equal to or greater than the dielectric constant of silicon oxide. Passivation layer 42 may be formed of or comprise an inorganic dielectric material, which may include a material selected from, and is not limited to, Undoped Silicate Glass (USG), silicon nitride (SiN), silicon oxide (SiO₂), silicon oxy-nitride (SiON), silicon oxy-carbide (SiOC), or the like, combinations thereof, and/or multi-layers thereof. In accordance with some embodiments, the top surfaces of top dielectric layer 38T and metal lines 34T are level with one another. Accordingly, passivation layer 42 may be a planar layer.

In accordance with some embodiments, vias 44 are formed in passivation layer 42 to electrically connect to the underlying top metal features 34T. Metal pads 46 are further formed over vias 44. The corresponding process is shown as process 202 in the process flow 200 as shown in FIG. 19. In accordance with some embodiments, metal pads 46 comprise aluminum, aluminum copper, copper, or the like. Metal pads 46 may have thickness T1 in the range between about 14 kÅ and about 60 kÅ in accordance with some embodiments.

In accordance with some embodiments, vias 44 and metal pads 46 are formed in a same process. The formation process may include etching passivation layer 42 to form openings, depositing a metal layer including first portions extending into the openings and second portions over the passivation layer 42, and patterning the metal layer to form vias 44 and metal pads 46. In accordance alternative embodiments, the formation process may include depositing a metal seed layer, forming a patterned plating mask, and plating a metal layer over the metal seed layer and extending into the openings. The patterned plating mask is then removed, followed by etching the portions of the metal seed layer previously covered by the plating mask. In accordance with yet alternative embodiments, vias 44 and metal pads 46 are formed separately, with vias 44 being formed in a single damascene process, and metal pads 46 being formed through deposition and patterning.

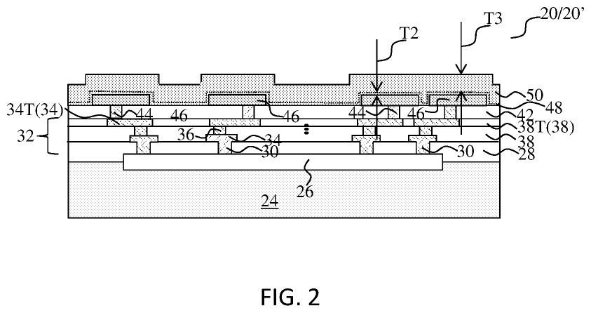

Referring to FIG. 2, in accordance with some embodiments, pre-layer 48 is deposited. The corresponding process is shown as process 204 in the process flow 200 as shown in FIG. 19. Pre-layer 48 may be formed of a material that has good adhesion with the underlying metal pads 46 and passivation layer 42. Pre-layer 48 may also act as a barrier for preventing the out-diffusion of the materials of metal pads 46. Pre-layer 48 thus may also be referred to as an adhesion layer or a barrier. For example, pre-layer 48 may be formed of or comprise a nitride-based dielectric material such as silicon nitride, silicon oxynitride, silicon carbo-nitride, or the like. Pre-layer 48 is formed using a conformal deposition process such as Atomic Layer Deposition (ALD), Chemical Vapor Deposition (CVD), or the like.

In accordance with alternative embodiments, pre-layer 48 is not formed, and the subsequently formed passivation layer 50 is in direct contact with metal pads 46 and passivation layer 42. Accordingly, pre-layer 48 is shown using dashed lines to indicate that pre-layer 48 may be, or may not be, formed. In accordance with some embodiments, pre-layer 48, when formed, may have a thickness T2 in the range between about 0.1 kÅ and about 1 kÅ.

Next, as also shown in FIG. 2, passivation layer 50 (sometimes referred to as passivation-2 or pass-2) is formed. The corresponding process is shown as process 206 in the process flow 200 as shown in FIG. 19. In accordance with some embodiments, passivation layer 50 is formed of or comprises a dielectric material, which may include an oxide-based dielectric material such as Undoped Silicate Glass (USG), Spin-On Glass (SOG), silicon oxide, or the like. In accordance with alternative embodiments, passivation layer 50 is formed of or comprises a nitride-base dielectric material such as silicon nitride, silicon carbo-nitride, silicon oxynitride, or the like.

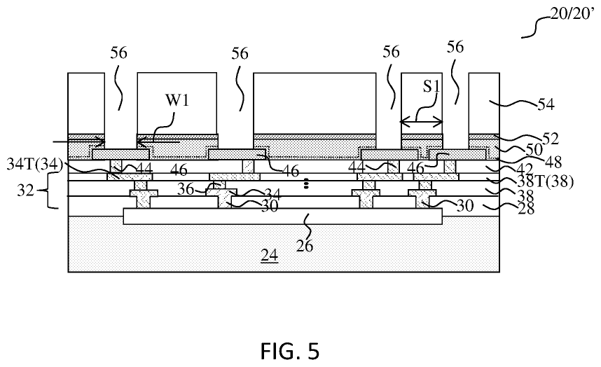

In accordance with yet alternative embodiments, passivation layer 50 is formed of a polymer, which is dispensed in a flowable form, and is then cured as a solid. In accordance with these embodiments, passivation layer 50 may be formed of a photo-sensitive polymer (such as polyimide, polybenzoxazole (PBO), benzocyclobutene (BCB), or the like.) or a non-photo-sensitive polymer. As will be discussed in detail in subsequent paragraphs, when formed of the photo-sensitive polymer, passivation layer 50 will be patterned through etching (using a photoresist as an etching mask), rather than through a light-exposure and development process. In accordance with some embodiment, passivation layer 50 is baked until it is cross-linked, so that it is not patterned by the subsequent light-exposure and development processes for patterning photoresist 54 (FIG. 5).

In accordance with some embodiments, passivation layer 50 is a single layer with an entirety of passivation layer 50 being formed of a homogeneous material. In accordance with alternative embodiments, passivation layer 50 is a composite layer comprising two or more sub layers. The materials of neighboring ones of the sub layers are different from each other, and the materials may be selected from the above-discussed candidate materials. Passivation layer 50 may be formed through spin-on coating or a deposition method such as CVD, High-Density Plasma (HDP) CVD, plasma enhanced CVD (PECVD) or the like.

In accordance with some embodiments, passivation layer 50 has a non-planar top surface. In accordance with some embodiments, the portions of passivation layer 50 directly over metal pads 46 have thickness T3 greater than about 10 kÅ, and thickness T3 may be in the range between about 10 kÅ and about 25 kÅ. The lowest portions of the top surface of passivation layer 50 are still higher than the top surfaces of metal pads 46 by a margin, so that after the subsequent planarization process, the planar top surface of passivation layer 50 is higher than the top surfaces of metal pads 46 by a portion having an adequate thickness.

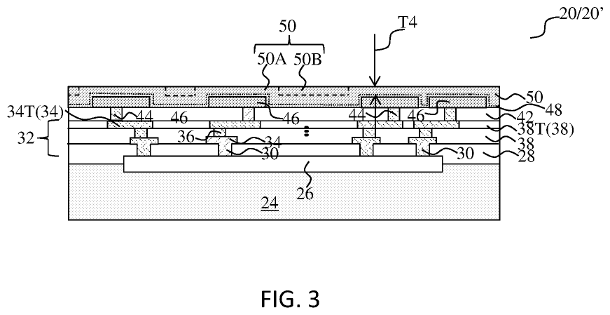

Referring to FIG. 3, a planarization process is performed, for example, through a CMP process or a mechanical grinding process. The corresponding process is shown as process 208 in the process flow 200 as shown in FIG. 19. The entire top surface of passivation layer 50 is thus planar. In accordance with some embodiments, the portions of the passivation layer 50 directly over metal pads 46 have thickness T4, which may be in the range between about 7 kÅ and about 15 kÅ.

In accordance with some embodiments, due to the CMP process, the top surface of passivation layer comprises CMP scratches, which are shallow scratches caused by the grits in the polishing pad and the slurry. The shallow scratches are the indication of the planarization process. As a comparison, if no planarization process is performed, there are no scratches. The CMP scratches may include a first plurality of traces parallel to each other. Also, there may include a second plurality of traces that intercept the first plurality of traces, wherein the second plurality of traces are parallel to each other, but are not parallel to the first plurality of traces. The first plurality of traces and the second first plurality of traces may be curved, or may be straight.

In accordance with some embodiments in which passivation layer 50 comprises a plurality of sub layers, after the planarization process, a top sub layer is polished, and a lower sub layer under the top sub layer may be, or may not be exposed. FIG. 3 illustrates an example embodiment in which passivation layer 50 includes lower sub layer 50A and upper layer 50B, which are conformal layers as deposited. In accordance with some embodiments, after the planarization process, the lower layer 50A may have some portions exposed, and some other portions covered by the upper layer 50B. In accordance with alternative embodiments, after the planarization process, the entire lower sub layer 50A is covered by the polished upper layer 50B.

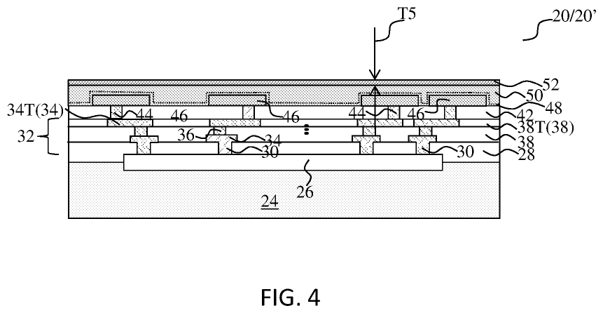

Referring to FIG. 4, dielectric capping layer 52 is deposited over passivation layer 50. The corresponding process is shown as process 210 in the process flow 200 as shown in FIG. 19. In accordance with some embodiments, dielectric capping layer 52 is also formed of a material that has good adhesion to the underlying and overlying layers. For example, dielectric capping layer 52 may be formed of or comprise a nitride-based dielectric material such as silicon nitride, silicon oxynitride, silicon carbo-nitride, or the like. Dielectric capping layer 52 is formed using a conformal deposition process such as ALD, CVD, or the like. The entire dielectric capping layer 52 may be planar. The thickness T5 of dielectric capping layer 52 may be in the range between about 5 kÅ and about 20 kÅ in accordance with some embodiments.

Referring to FIG. 5, etching mask 54 is formed and patterned. The corresponding process is shown as process 212 in the process flow 200 as shown in FIG. 19. In accordance with some embodiments, etching mask 54 comprises a photoresist, whose patterning includes placing a lithography mask (not shown) over etching mask 54, with the lithography mask including opaque patterns and transparent portions. A light exposure process is then performed to expose some portions of the photoresist, followed by a development process to remove some portions of the photoresist, forming the pattern as shown in FIG. 5. Openings 56 are formed in etching mask 54.

Etching mask 54 may (or may not) also have a single-layer structure, a dual-layer structure or a tri-layer structure, which includes an anti-reflective coating. The anti-reflective coating may help to reduce reflection, and the widths, spacings, and pitches of the resulting openings may be further reduced.

In accordance with some embodiments in which passivation layer 50 comprises a photo-sensitive material such as polyimide, PBO, BCB, or the like, at the time the etching mask 54 (photoresist) is light-exposed and patterned, the passivation layer 50 has already been adequately baked and thus is cross-linked. Accordingly, even if passivation layer 50 may receive the light for the light-exposure and may be exposed to the chemical used for developing etching mask 54 (in case openings 56 extend to passivation layer 50), passivation layer 50 is not developed, and openings 56 stops on the top surface of passivation layer 50.

In a subsequent process, dielectric capping layer 52, passivation layer 50, and pre-layer 48 (when formed) are patterned in an anisotropic etching process. Openings 56 thus extend downwardly to penetrate through dielectric capping layer 52, passivation layer 50, and pre-layer 48, with metal pads 46 being exposed to openings 56. The corresponding process is shown as process 214 in the process flow 200 as shown in FIG. 19. In accordance with some embodiments, the width W1 of openings 56 is greater than about 2 μm, and may be in the range between about 2 μm and about 10 μm.

In accordance with some embodiments in which passivation layer 50 comprises the photo-sensitive material such as polyimide, PBO, BCB, or the like, the formation of openings 56 in passivation layer 50 is through etching, rather than through light-exposure and development. The lithography process adopting photoresist as the etching mask has the advantageous feature of reducing pitch and spacing of the patterned features. Furthermore, the etching mask 54 may adopt a dual-layer structure or tri-layer structure, enabling the further reduction of the widths and spacings of openings 56. Accordingly, both of the width W1 of openings 56 and the spacing S1 between neighboring openings 56 are reduced, for example, to the range between about 2 μm and about 10 μm.

As a comparison, in a related art, a polyimide layer may be dispensed as a stress buffer layer and formed on metal pads 46, and the polyimide layer is not planarized through CMP or mechanical grinding. Accordingly, in order to have a relative flat top surface, the polyimide layer is thick, which may have a thickness in the range between about 4 μm and about 6 μm. The patterning of the polyimide layer is through light-exposure and development (rather than through etching using an overlying patterned photoresist). The widths and the spacings of the openings were thus unable to be reduced to meet the specification of advanced integrated circuits. For example, the widths and the spacings of the openings may be adversely limited to be greater than 10 μm. This significantly reduces the number of the vias that can be formed.

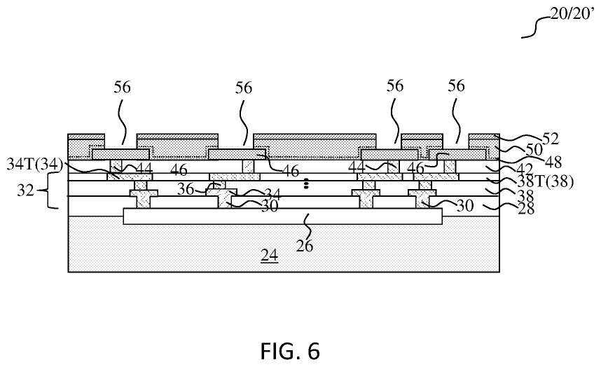

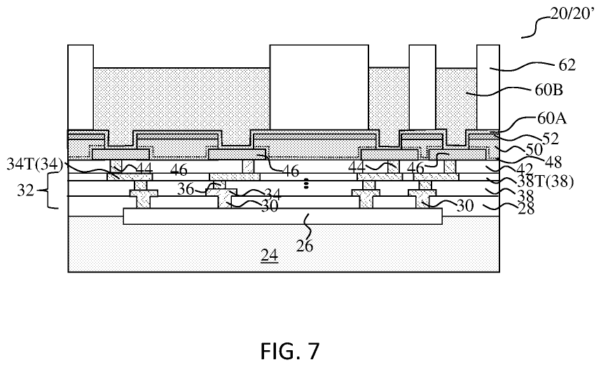

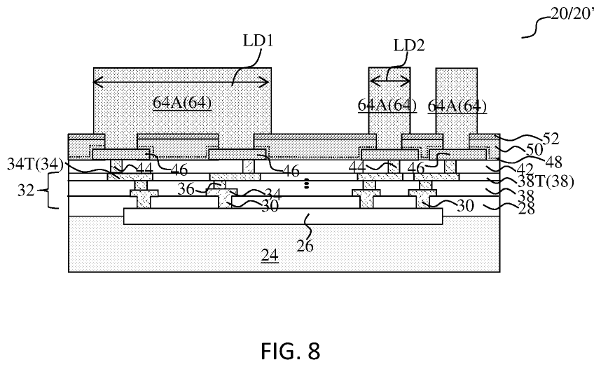

After the formation of openings 56, etching mask 54 is removed, for example, in an ashing process or an etching process, and the resulting structure is shown in FIG. 6. FIGS. 7 and 8 illustrate the formation of vias (pillars). The corresponding process is shown as process 216 in the process flow 200 as shown in FIG. 19. FIG. 7 illustrates the formation of metal seed layer 60A, which may be deposited through Physical Vapor Deposition (PVD) in accordance with some embodiments. Metal seed layer 60A may comprise a titanium layer, and a copper layer over the titanium layer. Plating mask 62 is formed on metal seed layer 60A, and is patterned, with some portions overlapping the via openings 56 (FIG. 6). Metallic material 60B is then deposited. In accordance with some embodiments, the deposition is performed through plating. Metallic material 60B may comprise copper, nickel, tungsten, cobalt, or the like, combinations thereof, and/or multi-layers thereof.

Plating mask 62 is then removed, and some portions of metal seed layer 60A are exposed. The exposed portions of the metal seed layer 60A are then removed through etching, with metallic material 60B being used as an etching mask. The remaining portions of metal seed layer 60A and metallic material 60B are collectively referred to as vias 64, as shown in FIG. 8. In accordance with some embodiments, vias 64 include line vias 64A, which has a line shape (elongated) when viewed in the top view, and may be connected to more than one metal pad 46. Vias 64 further include pillar via 64B, which has a pillar shape, and is less elongated when viewed in the top view.

In accordance with some embodiments, as shown in FIG. 8, line via 64A has greater lateral dimensions LD1 (lengths and widths) than the lateral dimensions (LD2) of pillar vias 64B. The spacings between neighboring line vias 64A may also be greater than the spacings between neighboring pillar vias 64B.

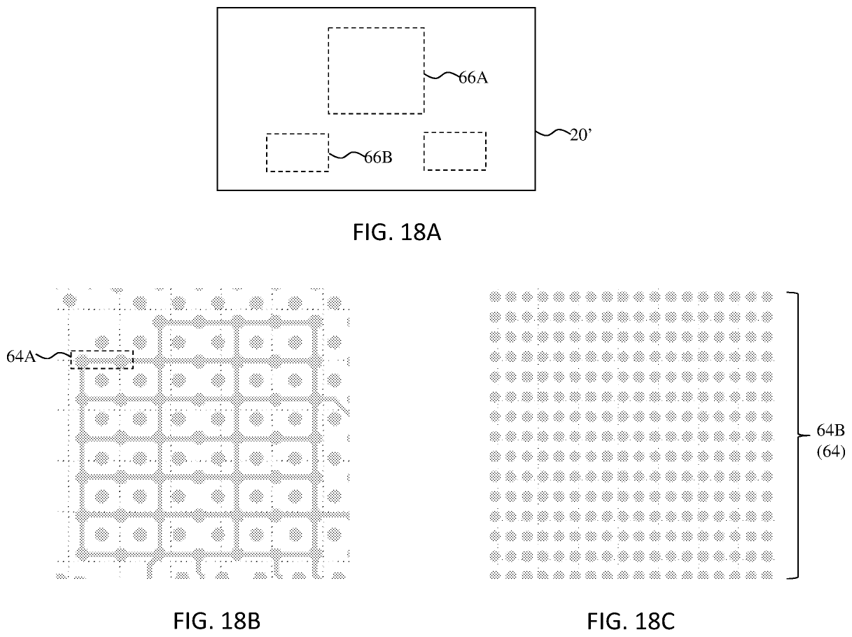

FIG. 18A illustrates a schematic top view of device die 20′ in accordance with some embodiments. A plurality of regions 66A, 66B, and 66C are schematically illustrated, which show where vias 64 can be located. In accordance with some embodiments, line vias 64A (FIG. 18B) may be located in one of regions 66A, 66B, and 66C, while pillar vias 64B (FIG. 18C) may be located in another one of regions 66A, 66B, and 66C.

FIG. 18B illustrates the top view of the line vias 64A in accordance with some embodiments. In the illustrated example, a line via 64A is formed as having a grid pattern, with the line(s) in line vias 64A including horizontal lines and vertical lines. In accordance with these embodiments, the grid-shaped line via may be used for electrical grounding, electromagnetic shielding, thermal dissipation, or the like. In accordance with alternative embodiments, instead of forming a grid, a line via 64A may be an elongated strip when viewed in the top view. FIG. 18C illustrates the top view of a plurality of pillar vias 64B, which may be arranged as an array.

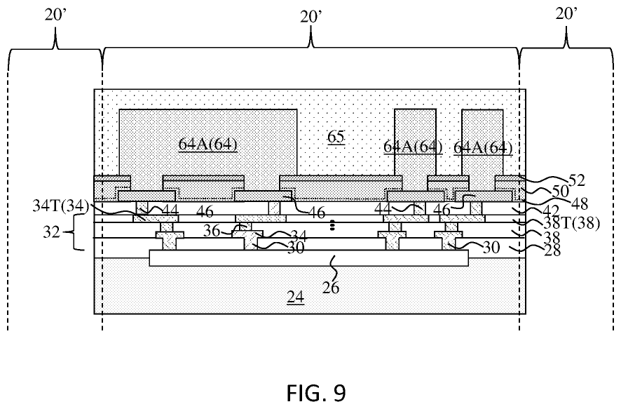

In a subsequent process, as shown in FIG. 9, dielectric layer 65 is formed to embed vias 64 therein. The corresponding process is shown as process 218 in the process flow 200 as shown in FIG. 19. In accordance with some embodiments, dielectric layer 65 is formed of or comprises polyimide, PBO, BCB, or the like. The top surface of dielectric layer 65 is higher than the top surfaces of vias 64, and hence vias 64 are covered. Wafer 20 is then singulated, for example, sawed into a plurality of discrete dies 20′. The corresponding process is shown as process 220 in the process flow 200 as shown in FIG. 19. In the sawing process, wafer 20 may be fixed on a dicing tape (not shown), which is further fixed on a frame (not shown).

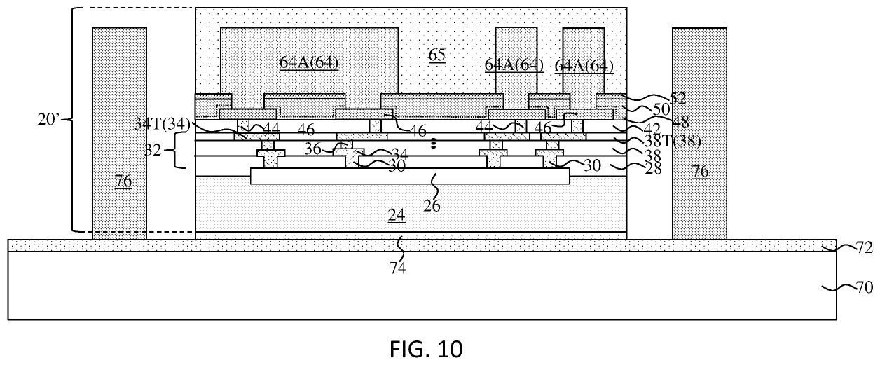

Referring to FIG. 10, carrier 70 is provided, with release film 72 being coated on carrier 70. Carrier 70 may be a glass carrier, a silicon wafer, an organic carrier, or the like. Release film 72 may be formed of a polymer-based material and/or an epoxy-based thermal-release material, such as a LTHC material. There may be a dielectric buffer layer (not shown) such as a PBO layer formed on release film 72.

Metal posts 76 are formed over carrier 70, for example, on the dielectric buffer layer (not shown). The corresponding process is shown as process 222 in the process flow 200 as shown in FIG. 19. In accordance with some embodiments, the formation of metal posts 76 includes depositing a metal seed layer, forming a plating mask, plating the metal posts 76 in the openings of the plating mask, removing the plating mask, and etching portions of the metal seed layer previously covered by the plating mask.

Device die 20′ is also attached to carrier 70 through die-attach film 74, which is an adhesive film. The corresponding process is shown as process 224 in the process flow 200 as shown in FIG. 19. Although one device die 20′ is shown, there may be a plurality of device dies 20′ attached to carrier 70.

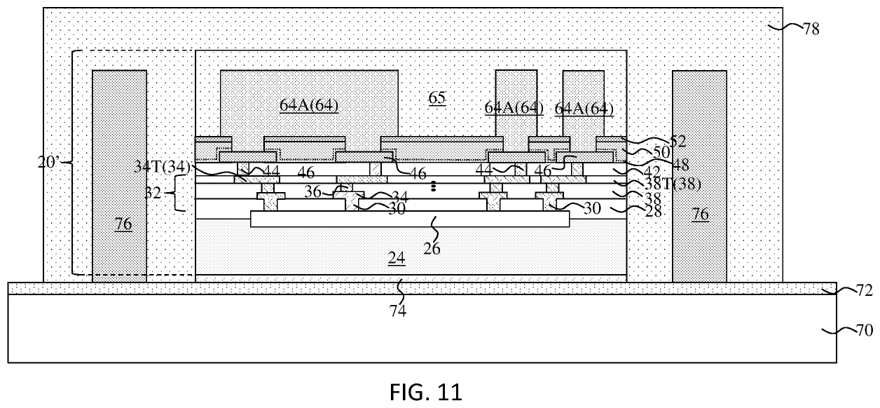

Next, device dies 20′ and metal posts 76 are encapsulated in encapsulant 78, as shown in FIG. 11. The corresponding process is shown as process 226 in the process flow 200 as shown in FIG. 19. Encapsulant 78 fills the gaps between neighboring metal posts 76 and the gaps between metal posts 76 and device dies 20′. Encapsulant 78 may include a molding compound, a molding underfill, an epoxy, and/or a resin. The top surface of encapsulant 78 is higher than the top ends of vias 64. The molding compound may include a base material, which may be a polymer, a resin, an epoxy, or the like, and filler particles (not shown) in the base material. The filler particles may be dielectric particles of SiO₂, Al₂O₃, silica, or the like, and may have spherical shapes. Also, the spherical filler particles may have the same or different diameters.

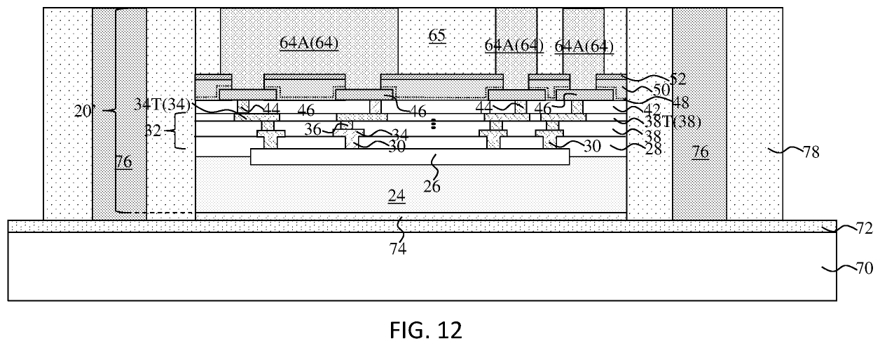

As shown in FIG. 12, a planarization process such as a CMP process or a mechanical grinding process is performed to thin encapsulant 78 and dielectric layer 65, until metal posts 76 and vias 64 are all exposed. The corresponding process is shown as process 228 in the process flow 200 as shown in FIG. 19. Metal posts 76 are referred to as through-vias 76 hereinafter.

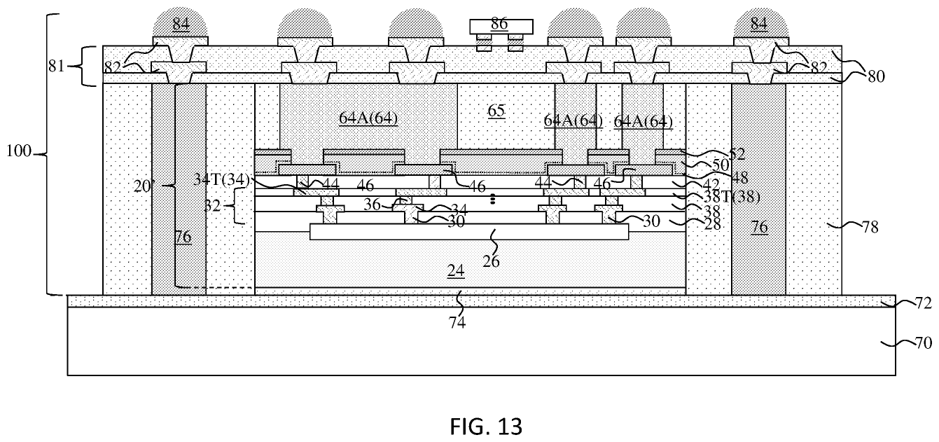

FIG. 13 illustrates the formation of a front-side redistribution structure 81, which includes dielectric layers 80 and RDLs 82. The corresponding process is shown as process 230 in the process flow 200 as shown in FIG. 19. In accordance with some embodiments, dielectric layers 80 may be formed of a polymer such as PBO, polyimide, or the like. The formation of a dielectric layer 80 may include coating dielectric layers 80 in a flowable form, and then curing the dielectric layer 80. In accordance with alternative embodiments of the present disclosure, dielectric layers 80 are formed of an inorganic dielectric material such as silicon nitride, silicon oxide, or the like. The formation method may include CVD, ALD, Plasma-Enhanced Chemical Vapor Deposition (PECVD), or other applicable deposition methods.

RDLs 82 are formed to electrically connect to device die 20′ and through-vias 76. Each of RDLs 82 includes a via portion formed in the respective underlying dielectric layer 80, and a trace portion (metal line) over the respective dielectric layer 80. In accordance with some embodiments of the present disclosure, each layer of RDLs 82 is formed in a plating process, which includes depositing a metal seed layer (not shown), forming and patterning a photoresist (not shown) over the metal seed layer, and plating a metallic material such as copper and/or aluminum over the metal seed layer. The patterned photoresist is then removed, followed by etching the portions of the metal seed layer previously covered by the patterned photoresist.

As also shown in FIG. 13, electrical connectors 84 are formed. The formation of electrical connectors 84 may include placing solder balls on the exposed portions of RDLs 82, and then reflowing the solder balls, and hence electrical connectors 84 are solder regions. In accordance with alternative embodiments of the present disclosure, the formation of electrical connectors 84 includes performing a plating step to form solder layers over RDLs 82, and then reflowing the solder layers. Electrical connectors 84 may also include non-solder metal pillars, or metal pillars and solder caps over the non-solder metal pillars, which may also be formed through plating. Throughout the description, the structure over release film 72 is referred to as reconstructed wafer 100.

FIG. 13 also illustrates the bonding of device 86 to redistribution structure 81. In accordance with some embodiments, device 86 includes an Independent Passive Device (IPD) such as a capacitor die, an inductor die, or the like.

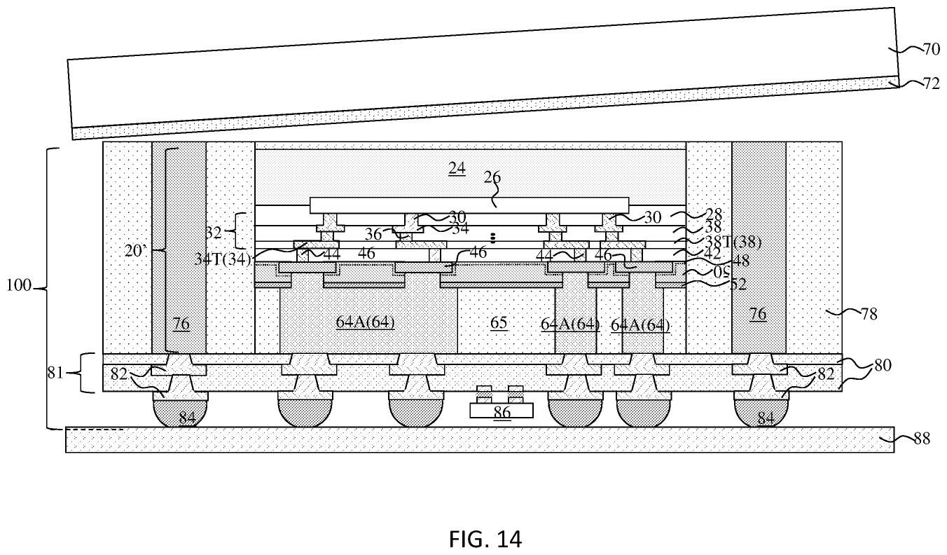

Next, referring to FIG. 14, reconstructed wafer 100 is placed on tape 88, which is attached to a frame (not shown). In accordance with some embodiments of the present disclosure, electrical connectors 84 are in contact with tape 88. Next, the structure on layer 72 is de-bonded from carrier 70, as also shown in FIG. 14. The corresponding process is shown as process 232 in the process flow 200 as shown in FIG. 19. In the de-bonding, a light beam is projected on LTHC coating material 72, and the light beam penetrates through the transparent carrier 70. In accordance with some embodiments, the light beam is a laser beam, which scans through the entire LTHC coating material 72.

As a result of the light-exposure (such as the laser scanning), carrier 70 may be lifted off from LTHC coating material 72, and hence reconstructed wafer 100 is de-bonded (demounted) from carrier 70.

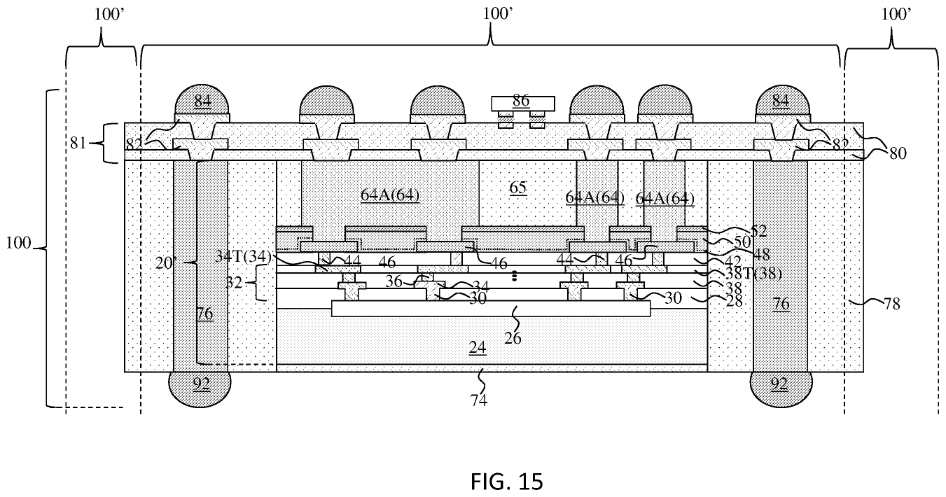

FIG. 15 illustrates the formation of electrical connectors 92, which may include solder regions in accordance with some embodiments. The corresponding process is shown as process 234 in the process flow 200 as shown in FIG. 19. In a subsequent process, reconstructed wafer 100 is sawed apart into a plurality of packages 100′. The corresponding process is shown as process 236 in the process flow 200 as shown in FIG. 19.

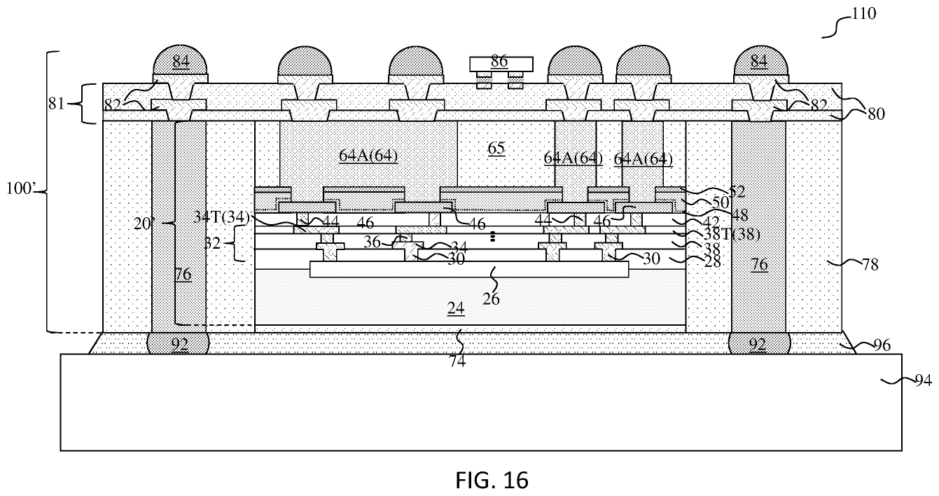

FIG. 16 also illustrates the bonding of package 100′ to package component 94, so that package 110 is formed. The corresponding process is shown as process 238 in the process flow 200 as shown in FIG. 19. The bonding is performed through solder regions 92, which join through-vias 76 to the metal pads of the package component 94. In accordance with some embodiments, package component 94 may include a package substrate, an interposer, a printed circuit board, a package, or the like. Underfill 96 is disposed between package 100′ and package component 94.

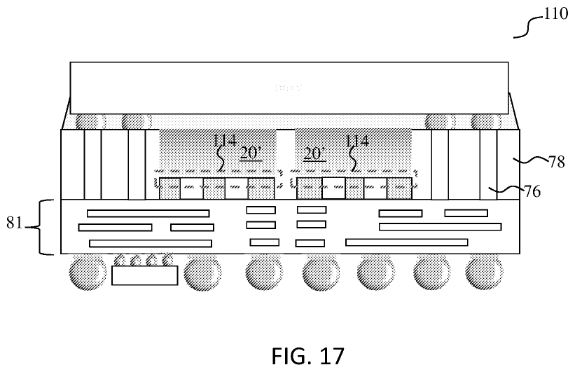

FIG. 17 illustrates a package 110 incorporating the device dies 20 in accordance with some embodiments. Regions 114 illustrate the regions in which the passivation layer 50 (which have planarized surfaces) and vias 64 are formed. Package 110 includes two device dies 20′ in accordance with some embodiments.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By forming and planarizing a passivation layer, there is no need to form a thick polyimide layer as a stress buffer layer that has a relatively planar top surface. A photolithography process using a patterned lithography mask is performed to pattern the passivation layer. The pitches, widths, and spacings of the vias are thus reduced. Also, by planarizing and thinning the passivation layer, the thickness of the passivation layer is reduced.

In accordance with some embodiments of the present disclosure, a method comprises forming a metal pad; depositing a passivation layer on the metal pad; planarizing the passivation layer, so that the passivation layer comprises a planar top surface; etching the passivation layer to form an opening in the passivation layer, wherein the metal pad is exposed to the opening; forming a conductive via comprising a lower portion in the opening, and an upper portion higher than the passivation layer; and dispensing a polymer layer covering the conductive via.

In an embodiment, the method further comprises sawing a wafer comprising the conductive via and the polymer layer to separate a plurality of device dies in the wafer; encapsulating a device die of the plurality of device dies in an encapsulant; and polishing the encapsulant and the device die to reveal the conductive via. In an embodiment, the method further comprises, when the metal pad is formed, forming an additional metal pad, wherein the conductive via is a line via that electrically connects the metal pad to the additional metal pad. In an embodiment, the method further comprises, before the passivation layer is formed, depositing a pre-layer on the metal pad using a conformal deposition process.

In an embodiment, the method further comprises, after the passivation layer is planarized and before the passivation layer is etched, depositing a capping layer on the metal pad. In an embodiment, the etching the passivation layer comprises forming a patterned photoresist over the passivation layer, wherein the passivation layer is etched using the patterned photoresist as an etching mask. In an embodiment, the depositing the passivation layer comprises depositing an inorganic dielectric layer.

In an embodiment, the depositing the passivation layer comprises depositing an additional polymer layer. In an embodiment, the depositing the passivation layer comprises depositing a homogenous material, and an entirety of the passivation layer is formed of the homogenous material. In an embodiment, the depositing the passivation layer comprises depositing a plurality of sub layers comprising different dielectric materials.

In accordance with some embodiments of the present disclosure, a structure comprises a metal pad; a passivation layer comprising a first portion overlapping the metal pad, and a second portion offset from the metal pad, wherein top surfaces of the first portion and the second portion are coplanar; a conductive via comprising a lower portion in the passivation layer; and an upper portion over the passivation layer; and a dielectric layer, wherein the upper portion of the conductive via is in the dielectric layer.

In an embodiment, the structure further comprises a pre-layer between the metal pad and the passivation layer, wherein the pre-layer comprises a vertical portion and a horizontal portion having a same thickness. In an embodiment, the structure further comprises a dielectric capping layer over the passivation layer, wherein the lower portion of the conductive via is further in the dielectric capping layer. In an embodiment, an entirety of the dielectric capping layer is planar. In an embodiment, the passivation layer comprises an inorganic dielectric material. In an embodiment, the passivation layer comprises an organic dielectric material.

In accordance with some embodiments of the present disclosure, a structure comprises a first metal pad and a second metal pad; at least one dielectric layer comprising a passivation layer, wherein the passivation layer comprises a first portion overlapping the first metal pad; a second portion overlapping the second metal pad; and a third portion connecting the first portion to the second portion, wherein top surfaces of the first portion, the second portion, and the third portion are coplanar; and a conductive via comprising a lower portion in the passivation layer; and an upper portion over the passivation layer, wherein the upper portion forms a horizontal interface with a top surface of the first portion of the at least one dielectric layer.

In an embodiment, the top surfaces comprise a plurality of scratching marks. In an embodiment, the structure further comprises a dielectric capping layer over the passivation layer, wherein the lower portion of the conductive via is further in the dielectric capping layer. In an embodiment, the structure further comprises a pre-layer under the passivation layer, wherein the lower portion of the conductive via is further in the pre-layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a metal pad;
depositing a passivation layer on the metal pad;
planarizing the passivation layer, so that the passivation layer comprises a planar top surface;
etching the passivation layer to form an opening in the passivation layer, wherein the metal pad is exposed to the opening;
forming a conductive via comprising a lower portion in the opening, and an upper portion higher than the passivation layer; and
dispensing a polymer layer covering the conductive via.

2. The method of claim 1 further comprising:
sawing a wafer comprising the conductive via and the polymer layer to separate a plurality of device dies in the wafer;
encapsulating a device die of the plurality of device dies in an encapsulant; and
polishing the encapsulant and the device die to reveal the conductive via.

3. The method of claim 1 further comprising, when the metal pad is formed, forming an additional metal pad, wherein the conductive via is a line via that electrically connects the metal pad to the additional metal pad.

4. The method of claim 1 further comprising, before the passivation layer is formed, depositing a pre-layer on the metal pad using a conformal deposition process.

5. The method of claim 1 further comprising, after the passivation layer is planarized and before the passivation layer is etched, depositing a capping layer on the metal pad.

6. The method of claim 1, wherein the etching the passivation layer comprises:
forming a patterned photoresist over the passivation layer, wherein the passivation layer is etched using the patterned photoresist as an etching mask.

7. The method of claim 1, wherein the depositing the passivation layer comprises depositing an inorganic dielectric layer.

8. The method of claim 1, wherein the depositing the passivation layer comprises depositing an additional polymer layer.

9. The method of claim 1, wherein the depositing the passivation layer comprises depositing a homogenous material, and an entirety of the passivation layer is formed of the homogenous material.

10. The method of claim 1, wherein the depositing the passivation layer comprises depositing a plurality of sub layers comprising different dielectric materials.

11. A structure comprising:
a metal pad;
a passivation layer comprising a first portion overlapping the metal pad, and a second portion offset from the metal pad, wherein top surfaces of the first portion and the second portion are coplanar;
a conductive via comprising:
a lower portion in the passivation layer; and
an upper portion over the passivation layer; and
a dielectric layer, wherein the upper portion of the conductive via is in the dielectric layer.

12. The structure of claim 11 further comprising a pre-layer between the metal pad and the passivation layer, wherein the pre-layer comprises a vertical portion and a horizontal portion having a same thickness.

13. The structure of claim 11 further comprising a dielectric capping layer over the passivation layer, wherein the lower portion of the conductive via is further in the dielectric capping layer.

14. The structure of claim 13, wherein an entirety of the dielectric capping layer is planar.

15. The structure of claim 11, wherein the conductive via and the dielectric layer are comprised in a device die, and the structure further comprises:
an encapsulant encapsulating the device die therein; and
a redistribution structure comprising a plurality of redistribution lines, wherein the plurality of redistribution lines are over and electrically coupled to the device die.

16. The structure of claim 15 further comprising a through-via in the encapsulant, wherein the through-via is electrically coupled to one of the plurality of redistribution lines.

17. A structure comprising:
a first metal pad and a second metal pad;
at least one dielectric layer comprising a passivation layer, wherein the passivation layer comprises:
a first portion overlapping the first metal pad;
a second portion overlapping the second metal pad; and
a third portion connecting the first portion to the second portion, wherein top surfaces of the first portion, the second portion, and the third portion are coplanar; and
a conductive via comprising:
a lower portion in the passivation layer; and
an upper portion over the passivation layer, wherein the upper portion forms a horizontal interface with a top surface of the first portion of the at least one dielectric layer.

18. The structure of claim 17 further comprising:
an encapsulant contacting opposite sidewalls of the at least one dielectric layer;
a through-via penetrating through the encapsulant; and
a plurality of redistribution lines over and electrically coupling to the conductive via and the through-via.

19. The structure of claim 17 further comprising a dielectric capping layer over the passivation layer, wherein the lower portion of the conductive via is further in the dielectric capping layer.

20. The structure of claim 17 further comprising a pre-layer under the passivation layer, wherein the lower portion of the conductive via is further in the pre-layer.
